(19) United States
(12) Patent Application Publication
(10) Pub. No.: US 2008/0054294 A1
(43) Pub. Date: Mar. 6, 2008

(54) NITRIDE SEMICONDUCTOR SUBSTRATE AND METHOD OF MANUFACTURING THE SAME

(75) Inventors: Chih-Ming Lai, Pingtung County (TW); Jenq-Dar Tsay, Kaohsiung City (TW); Wen-Yueh Liu, Taipei City (TW); Yih-Der Guo, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: INDUSTRIAL TECHNOLOGY RESEARCH INSTITUTE, Hsinchu (TW)

(21) Appl. No.: 11/562,422

(22) Filed: Nov. 22, 2006

(30) Foreign Application Priority Data
Sep. 5, 2006 (TW) 95132698

(51) Int. Cl. H01L 33/00

(52) U.S. Cl. 257/103

(57) ABSTRACT

The present invention relates to a method of forming a nitride semiconductor substrate. This method includes steps of providing a substrate and then forming an epitaxy layer on the substrate. A patterned mask layer is formed on the epitaxy layer, wherein the patterned mask layer exposes a portion of the epitaxy layer. Next, an oxidation process is performed to oxidize the exposed epitaxy layer so as to form a plurality of dislocation blocking structures. The patterned mask layer is then removed. Further, a nitride semiconductor layer is formed on the epitaxy layer having the dislocation blocking structures.

### CROSS-REFERENCE TO RELATED APPLICATION

This application claims the priority benefit of Taiwan application serial no. 95132698, filed Sep. 5, 2006. All disclosure of the Taiwan application is incorporated herein by reference.

### BACKGROUND OF THE INVENTION

1. Field of the Invention

The present invention relates to a semiconductor substrate of group III-V and a method of manufacturing the same, and more particularly to a nitride semiconductor substrate and a method of manufacturing the same.

2. Description of Related Art

In the recent years, light emitting diodes (LED) and laser diodes (LD) have been prevailing in commercial use. For example, a mixture of blue and yellow phosphors made of gallium nitride (GaN) is capable of generating white light, which leads to a higher luminance and substantially lower power consumption than a conventional light bulb. In addition, the LED has a lifetime of more than tens of thousand hours, longer than that of conventional light bulbs.

The major components of red, green, blue, and ultraviolet LEDs obtained commercially are mostly GaN-series compound. However, since aluminum oxide substrate itself is different from GaN series in lattice constant, thermal expansion coefficients and chemical properties, the GaN layer growing on a heterogeneous substrate (e.g. a silicon substrate, a silicon carbide substrate, or an aluminum oxide substrate) may have linear defects and dislocations. The dislocations extend together with the increasing thickness of the growing GaN layer, resulting in the formation of threading dislocations. The foresaid defects would affect the laser performance of the ultraviolet LEDs and of the GaN-series compound and reduce their lifetime.

In order to reduce the threading dislocations, several substrate structures are then developed according to the prior art. FIG. 1 is a simplified sectional view illustrating a conventional nitride substrate of group III. Referring to FIG. 1, a GaN buffer layer 102 is disposed on a substrate 100, and several barrier structures 104 are disposed on the GaN buffer layer 102. Then, a semiconductor layer 106, i.e. a GaN epitaxy layer, is grown on the GaN buffer layer exposed among the barrier structures 104 and covers the barrier structures 104. In this substrate structure, the barrier structures are used to block some dislocations, so that a portion of the GaN epitaxy layer disposed on the barrier structures generates no threading dislocations. However, the barrier structures 104 are formed through at least once performance of photolithography and etching process, and vacuum apparatuses are also required to this manufacturing process; thus, the steps are more complicated and the cost is higher.

FIG. 2 is a simplified sectional view illustrating another conventional nitride substrate of group III. Referring to FIG. 2, a buffer layer 202 and a seed layer 204 are formed on the substrate 200. Trenches 206 passing through the buffer layer 202 and the seed layer 204 are then formed in the substrate 200. Namely, the buffer layer 202 and the seed layer 204 are patterned into strip or dot structures. A selective lateral overgrowth technique of a heterogeneous structure is called “pendeo-epitaxy” (PE) whereby the GaN epitaxy layer is simply suspended from and laterally grown on the sidewalls of the striped seed layer 204, such that the GaN epitaxy layer covers the striped seed layer 204 so as to block parts of the threading dislocations in a vertical direction. Similar to the barrier structures 104 illustrated in FIG. 1, the trenches 206 passing through the buffer layer 202 and the seed layer 204 are formed through at least once performance of photolithography and etching process, and vacuum apparatuses are also required for the manufacturing process; thus these steps are more complicated and the cost is higher.

### SUMMARY OF THE INVENTION

The present invention is directly to a manufacturing method of a nitride semiconductor substrate so as to reduce the manufacturing cost.

The present invention is also directly to a manufacturing method of a nitride semiconductor substrate so as to simplify the manufacturing process.

The present invention is directly to a nitride semiconductor substrate so as to reduce the dislocation density of the nitride semiconductor layer.

The present invention provides a manufacturing method of a nitride semiconductor substrate. A substrate is provided and an epitaxy layer is formed on the substrate. Then, a patterned mask layer is formed on the epitaxy layer, wherein the patterned mask layer exposes a portion of the epitaxy layer. Next, an oxidation process is performed to completely oxidize the exposed epitaxy layer so as to form a plurality of dislocation blocking structures. The patterned mask layer is removed. Then, a nitride semiconductor layer is formed on the epitaxy layer having the dislocation blocking structures.

The present invention further provides a manufacturing method of a nitride semiconductor substrate. A substrate having an epitaxy layer thereon is provided. Then, a patterned mask layer is formed on the epitaxy layer, wherein the patterned mask layer exposes a portion of the epitaxy layer. Next, an oxidation process is performed to partly oxidize the exposed epitaxy layer so as to form a plurality of dislocation blocking structures. The patterned mask layer is removed. Finally a nitride semiconductor layer is formed to cover the epitaxy layer.

The present invention also provides a nitride semiconductor substrate comprising a substrate, a nitride semiconductor layer, a plurality of blocking structures, and an epitaxy layer._{]} The nitride semiconductor layer is disposed on the substrate. The blocking structures are disposed between substrate and nitride semiconductor layer. The epitaxy layer fills the space between blocking structures.

Due to the oxide porous characteristic of the dislocation blocking structures/blocking structures, the nitride semiconductor layer does not form epitaxy on the dislocation blocking structures/blocking structures, but forms epitaxy on the surface of epitaxy layer. The nitride semiconductor layer grows in a lateral direction so as to block parts of the threading dislocations in the nitride semiconductor layer. Therefore, the threading dislocation density of the grown nitride semiconductor layer is reduced. Besides, the technique of oxidation process is used to directly oxidize the epitaxy layer on the substrate so as to form the dislocation blocking structures/blocking structures. Compared to the prior art of applied etching process to form barrier structures or trenches, this present invention can reduce the manufacturing cost.

In order to the make aforementioned and other objects, features and advantages of the present invention comprehensible, a preferred embodiment accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a simplified sectional view illustrating a conventional nitride substrate of group III.

FIG. 2 is a simplified sectional view illustrating another conventional nitride substrate of group III.

FIGS. 3A to 3C depict a manufacturing method of a nitride semiconductor substrate according to one embodiment of the present invention.

FIGS. 4A to 4C depict a manufacturing method of a nitride semiconductor substrate according to another embodiment of the present invention.

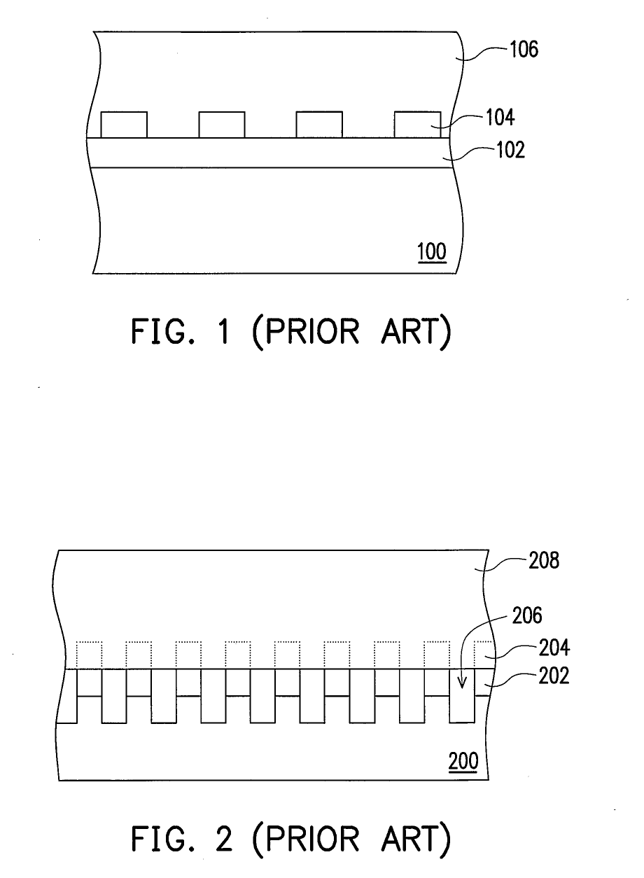

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

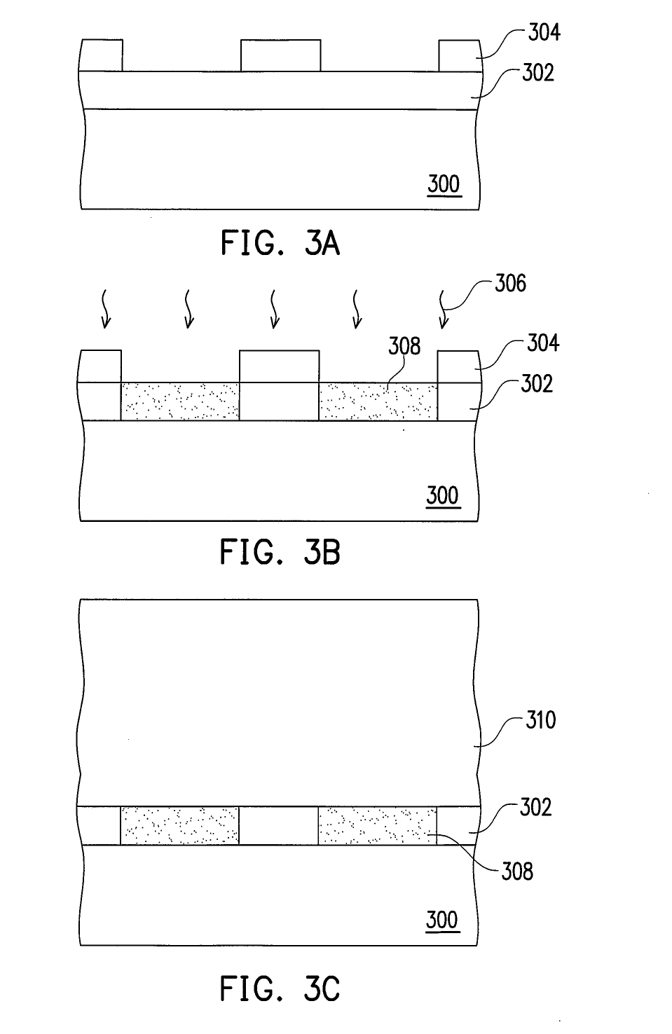

FIGS. 3A to 3C depict a manufacturing method of a nitride semiconductor substrate according to one preferred embodiment of the present invention.

Firstly, refer to FIG. 3A, a substrate 300 is provided. Next, an epitaxy layer 302 is formed on the substrate 300. Next, a patterned mask layer 304 is formed on the epitaxy layer 302. The patterned mask layer 304 exposes a portion of the epitaxy layer 302. The patterned mask layer 304 is, for example, a photoresist layer. Then, refer to FIG. 3B, an oxidation process 306 is performed by using the patterned mask layer 304 as a mask to completely oxidize the exposed epitaxy layer 302 to form a plurality of blocking structures 308, namely the dislocation blocking structures.

It should be noted that in one embodiment of the present invention, when the material of the substrate 300 is selected from a group consisting of silicon, silicon carbide, aluminum oxide, sapphire, zinc oxide, magnesium oxide and a combination thereof, the epitaxy layer 302 formed on the substrate 300 is, for example, a nitride epitaxy material layer. The foresaid nitride epitaxy material layer is selected from one group consisting of gallium nitride (GaN), indium nitride (InN), aluminum nitride (AlN), indium gallium nitride, aluminum gallium nitride, indium aluminum nitride, aluminum indium gallium nitride and a combination thereof. When the materials of substrate 300 and epitaxy layer 302 are as mentioned above, the oxidation process 306 is performed. In the oxidation process 306, the substrate 300 comprising epitaxy layer 302 and patterned mask layer 304 thereon is, under the room temperature of 0˜80° C., immersed in an electrolytic solution to proceed the oxidation so as to completely oxidize the exposed epitaxy layer; and in this way, the blocking structures 308 are formed. In this process, the pH value of the electrolytic solution is between 3 and 10. The way to prepare this electrolytic solution is to dissolve nitrilotriacetic acid in the potassium hydroxide solution. Besides, at the time the oxidation process 308 is performed, the process of high-energy light illuminating is proceeded. Namely, using the high-energy light, e.g. the ultraviolet light, accelerates the oxidation in the electrolytic solution. The wavelength of the foresaid high-energy light is shorter than that of the light which can penetrate the epitaxy layer 302.

In another embodiment, when the material of the substrate 300 is selected from a group consisting of gallium arsenide, gallium phosphide, gallium arsenide phosphide, gallium arsenide aluminum, other arsenide and phosphide and a combination thereof, the epitaxy layer 302 is, for example, an arsenide epitaxy material containing aluminum. The foresaid arsenide epitaxy material containing aluminum is, for example, an arsenide (Al_{X}Ga_{(1-X)}As) epitaxy material containing aluminum and gallium. Wherein, the X is larger than 0.8. That is, in the arsenide epitaxy material containing aluminum and galliumthe, the ratio between the aluminum atoms and the total number of aluminum atoms and the gallium atoms is larger than 0.8. When the materials of substrate 300 and epitaxy layer 302 are as mentioned above, the oxidation process 306 is performed. In the oxidation process 306, the substrate 300 comprising epitaxy layer 302 and patterned mask layer 304 thereon is, under the high temperature of 200˜600° C., placed in the condition of water vapor to proceed a wet oxidation step.

In the foresaid embodiment, the oxidation process 306 is performed to completely oxidize the exposed epitaxy layer so as to form the blocking structures 308. The material of the blocking structures 308 is selected from a group consisting of aluminum oxide, gallium oxide and a combination thereof.

Referring to FIG. 3C, the patterned mask layer 308 is removed. Next, a nitride semiconductor layer 310 is formed over the substrate 300. The way to form the nitride semiconductor layer 310 includes an epitaxial process, such as an organic-metal vapor epitaxy method or a metal-organic chemical vapor epitaxy method.

In the performance of the epitaxial process, due to the oxide porous characteristic of the blocking structures 308, the nitride semiconductor layer 310, such as gallium nitride, indium nitride, aluminum nitride, indium gallium nitride, aluminum gallium nitride, indium aluminum nitride, and aluminum indium gallium nitride semiconductor layer, does not form epitaxy on the blocking structures 308, but forms epitaxy on the surface of epitaxy layer 302, which fills the space between the blocking structures 308. The nitride semiconductor layer 310 grows in a lateral direction so as to block parts of the threading dislocations in the nitride semiconductor layer. Therefore, the threading dislocation density of the grown nitride semiconductor layer is reduced.

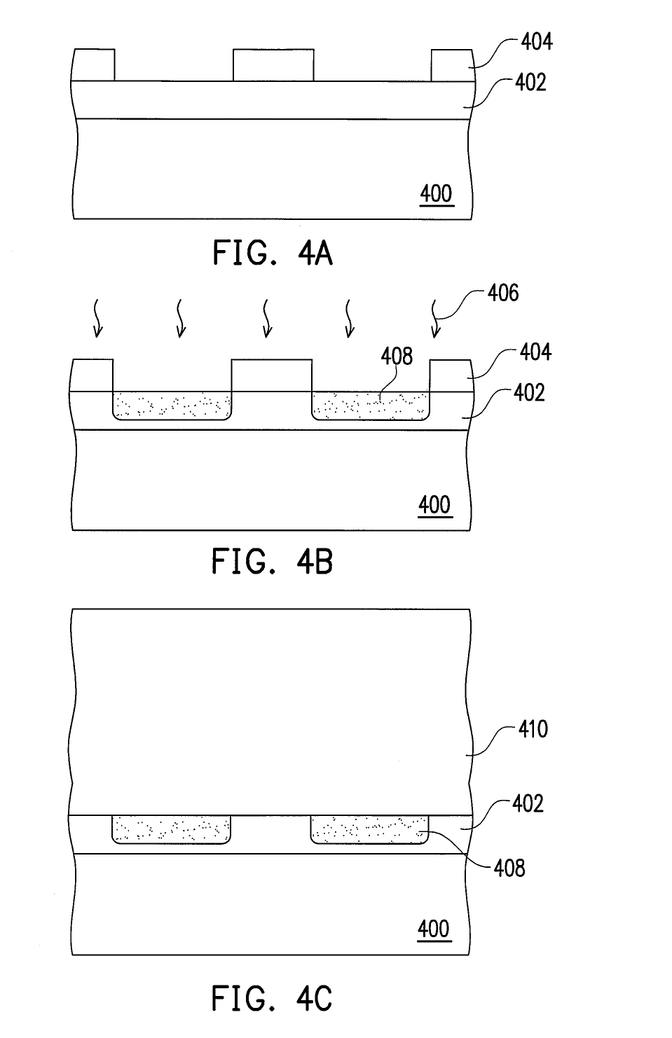

FIGS. 4A to 4C depict a manufacturing method of a nitride semiconductor substrate according to another preferred embodiment of the present invention.

Firstly, refer to FIG. 4A, a substrate 400 is provided. Next, an epitaxy layer 402 is formed on the substrate 400. Next, a patterned mask layer 404 is formed on the epitaxy layer 402. The patterned mask layer 404 exposes a portion of the epitaxy layer 402. The patterned mask layer 404 is, for example, a photoresist layer. Then, refer to FIG. 4B, an oxidation process 406 is performed by using the patterned mask layer 404 as a mask to partly oxidize the exposed epitaxy layer 402 so as to form a plurality of blocking structures 408, namely the dislocation blocking structures.

It sould be noted that in this embodiment, the blocking structures 408 are disposed in the epitaxy layer 402. Referring to the embodiment of 3A to 3C, the blocking structures 308 are disposed on the substrate 300, and at the same time, the epitaxy layer 302 is disposed on the substrate 300 and fills the space between blocking structures 308. Different from the blocking structures 308 illustrated in the embodiment of 3A to 3C, the blocking structures 408 in this present embodiment are disposed in the epitaxy layer 402, and the bottom of the blocking structure 408 is not directly contacted with the substrate 400.

Moreover, since the material of substrate 400 and epitaxy layer 402 in this embodiment is the same with the material of substrate 300 and epitaxy layer 302 in the previous embodiment, the detailed description of material will not be explained here. Similarly, the method to form the blocking structure 408 in the epitaxy layer 402 is the same with the method to form the blocking structure 308 in the previous embodiment; the detailed description is omitted here. Further, since the material of blocking structure 408, namely the oxide material, is the same with the material of blocking structure 308, no detailed descriptions are required here.

Then, refer to FIG. 4C, the patterned mask layer 408 is removed. Afterward, a nitride semiconductor layer 410 is formed over the substrate 400. The method to form this nitride semiconductor layer 410 is an epitaxial process, such as an organic-metal vapor epitaxy method or a metal-organic chemical vapor epitaxy method. In the performance of epitaxial process, due to the oxide porous characteristic of the blocking structure 408, the nitride semiconductor layer 410, such as nitride semiconductor layer of the gallium nitride, indium nitride, aluminum nitride, indium gallium nitride, aluminum gallium nitride, indium aluminum nitride, and aluminum indium gallium, does not form epitaxy on the blocking structure 408, but forms epitaxy on the surface of epitaxy layer 402. The nitride semiconductor layer 410 grows in a lateral direction so as to block parts of the threading dislocations in the nitride semiconductor layer. Therefore, the threading dislocation density of the grown nitride semiconductor layer is reduced.

Besides, the present invention uses the technique of oxidation process to directly oxidize the epitaxy layer on the substrate so as to form the blocking structure. Compared to the prior art of applied etching process to form blocking structure, this present invention can reduce the manufacturing cost.

Although the present invention has been disclosed above by the preferred embodiments, they are not intended to limit the present invention. Anybody skilled in the art can make some modifications and alteration without departing from the spirit and scope of the present invention. Therefore, the protecting range of the present invention falls in the appended claims.

What is claimed is:

1. A method of forming a nitride semiconductor substrate, comprising:
providing a substrate;
forming a epitaxy layer on the substrate;
forming a patterned mask layer on the epitaxy layer, wherein the patterned mask layer exposes a portion of the epitaxy layer;
performing an oxidation process to completely oxidize the exposed epitaxy layer so as to form a plurality of dislocation blocking structure;
removing the patterned mask layer; and
forming a nitride semiconductor layer on the epitaxy layer having the dislocation blocking structures.

2. The method of claim 1, wherein the material of the substrate is selected from a group consisting of silicon, silicon carbide, aluminum oxide, sapphire, zinc oxide, magnesium oxide and a combination thereof.

3. The method of claim 2, the epitaxy layer includes a nitride epitaxy material layer.

4. The method of claim 3, the material of the nitride epitaxy material layer is selected from a group consisting of gallium nitride, indium nitride, aluminum nitride, indium gallium nitride, gallium aluminum nitride, indium aluminum nitride, aluminum indium gallium nitride and a combination thereof.

5. The method of claim 2, wherein the oxidation process comprises a step of using an electrolytic solution.

6. The method of claim 5, wherein the pH value of the electrolytic solution is between 3 and 10.

7. The method of claim 5, wherein the oxidation process further comprises a step of performing a high-energy light illuminating.

8. The method of claim 7, wherein the high-energy light illuminating process comprises a step of using an ultraviolet light.

9. The method of claim 1, wherein the material of the substrate is selected from a group consisting of gallium arsenide, gallium phosphide, gallium arsenide phosphide, gallium arsenide aluminum and a combination thereof.

10. The method of claim 9, wherein the material of the epitaxy layer is selected from a group consisting of an arsenide epitaxy material containing aluminum, an arsenide epitaxy material containing aluminum and gallium and a combination thereof.

11. The method of claim 10, wherein the ratio between the aluminum atoms and the total number of aluminum atoms and gallium atoms in the arsenide epitaxy material containing aluminum and gallium is larger than 0.8.

12. The method of claim 9, wherein the oxidation process comprises a wet oxidation step.

13. The method of claim 12, wherein the wet oxidation step is performed in the condition of water vapor and under the temperature of 200˜600° C.

14. A method of manufacturing a nitride semiconductor substrate, comprising:
providing a substrate having an epitaxy layer thereon;
forming a patterned mask layer on the epitaxy layer, wherein the patterned mask layer exposes a portion of the epitaxy layer;
performing an oxidation process to oxidize the exposed epitaxy layer so as to form a plurality of dislocation blocking structures, wherein the dislocation blocking structures are disposed in the epitaxy layer.
removing the patterned mask layer; and
forming a nitride semiconductor layer to cover the epitaxy layer.

15. The method of claim 14, wherein the material of the substrate is selected from a group consisting of silicon, silicon carbide, aluminum oxide, sapphire, zinc oxide, magnesium oxide and a combination thereof.

16. The method of claim 15, the material of the epitaxy layer comprises a nitride epitaxy material layer, and the material of the nitride epitaxy material layer is selected from a group consisting of gallium nitride, indium nitride, aluminum nitride, indium gallium nitride, gallium aluminum nitride, indium aluminum nitride, aluminum indium gallium nitride and a combination thereof.

17. The method of claim 15, wherein the oxidation process comprises a step of using an electrolytic solution, and the pH value of the electrolytic solution is between 3 and 10.

18. The method of claim 15, wherein the oxidation process further comprises a step of performing a high-energy light illuminating.

19. The method of claim 15, wherein the material of the substrate is selected from a group consisting of gallium arsenide, gallium phosphide, gallium arsenide phosphide, gallium arsenide aluminum and a combination thereof.

20. The method of claim 19, wherein the material of the epitaxy layer is selected from a group consisting of an arsenide epitaxy material containing aluminum, an arsenide epitaxy material containing aluminum and gallium, and the ratio between the aluminum atoms and the total number of aluminum atoms and gallium atoms in the arsenide epitaxy material containing aluminum and gallium is larger than 0.8.

21. The method of claim 19, wherein the oxidation process comprises a wet oxidation step, which is performed in the condition of water vapor and under the temperature of 200˜600° C.

22. A nitride semiconductor substrate, comprising:
a substrate;
a nitride semiconductor layer disposed over the substrate;
a plurality of blocking structures disposed between the substrate and the nitride semiconductor layer; and
an epitaxy layer filling between the blocking structures.

23. The nitride semiconductor substrate as claimed in claim 22, wherein the material of the substrate is selected from a group consisting of silicon, silicon carbide, aluminum oxide, sapphire, zinc oxide, magnesium oxide and a combination thereof.

24. The nitride semiconductor substrate as claimed in claim 23, wherein the material of the epitaxy layer comprises a nitride epitaxy material layer, and the material of the nitride epitaxy material layer is selected from a group consisting of gallium nitride, indium nitride, aluminum nitride, indium gallium nitride, gallium aluminum nitride, indium aluminum nitride, aluminum indium gallium nitride and a combination thereof.

25. The nitride semiconductor substrate as claimed in claim 22, wherein the material of the substrate is selected from a group consisting of gallium arsenide, gallium phosphide, gallium arsenide phosphide, gallium arsenide aluminum and a combination thereof.

26. The nitride semiconductor substrate as claimed in claim 25, wherein the material of the epitaxy layer is selected from a group consisting of an arsenide epitaxy material containing aluminum, an arsenide epitaxy material containing aluminum and gallium, and the ratio between the aluminum atoms and the total number of aluminum atoms and gallium atoms in the arsenide epitaxy material containing aluminum and gallium is larger than 0.8.

27. The nitride semiconductor substrate as claimed in claim 22, wherein the material of the blocking structures at least comprises aluminum oxide or gallium oxide.
